(19) United States
(12) Patent Application Publication
(10) Pub. No.: US 2025/0098340 A1
(43) Pub. Date: Mar. 20, 2025

(54) LIGHT-RECEIVING DEVICE

(71) Applicant: KABUSHIKI KAISHA TOSHIBA, Tokyo (JP)

(72) Inventors: Yoshiaki SUGIZAKI, Fujisawa Kanagawa (JP); Yasutaka NISHIDA, Tama Tokyo (JP); Takashi YOSHIDA, Kashiwa Chiba (JP); Akiko YUZAWA, Minato Tokyo (JP); Miyu NAGAI, Yokohama Kanagawa (JP)

(73) Assignee: KABUSHIKI KAISHA TOSHIBA, Tokyo (JP)

(21) Appl. No.: 18/761,384

(22) Filed: Jul. 2, 2024

(30) Foreign Application Priority Data
Sep. 20, 2023 (JP) 2023-152027

(51) Int. Cl. H01L 31/113; H01L 31/02; H01L 31/028; H01L 31/0384

(52) U.S. Cl. CPC H10F 30/282; H10F 77/122; H10F 77/162; H10F 77/953

(57) ABSTRACT

A light-receiving device includes graphene including a light-receiving part; major electrodes electrically connected with the graphene, the major electrodes including a source electrode and a drain electrode, the light-receiving part being positioned between the source electrode and the drain electrode; a gate electrode electrically connected with the light-receiving part of the graphene via capacitive coupling; a circuit part electrically connected with the major electrode and the gate electrode; and an ionic substance contacting the light-receiving part of the graphene. The ionic substance is one of an anion having an acid dissociation constant of not less than 3 or a cation having an acid dissociation constant of not more than 11.

### CROSS-REFERENCE TO RELATED APPLICATION

This application is based upon and claims the benefit of priority from Japanese Patent Application No. 2023-152027, filed on Sep. 20, 2023; the entire contents of which are incorporated herein by reference.

### FIELD

Embodiments described herein relate generally to a light-receiving device.

### BACKGROUND

Graphene, a zero-gap material, can absorb light of all wavelengths, including infrared, when the Fermi level is at the Dirac point, and is therefore promising for applications as a wideband light-receiving element. To increase the light detection capability, a configuration has been proposed in which a fluorescent dye or gold nanoparticles are stacked on graphene. However, such a configuration responds only to specific wavelengths due to the dependence on the excitation spectra of the fluorescent dye or plasmons.

### BRIEF DESCRIPTION OF THE DRAWINGS

FIG. 1A is a schematic view of a light-receiving device of a first embodiment;

FIG. 1B is a schematic view of a light-receiving device of a second embodiment;

FIGS. 2A to 3A are graphs showing measurement results of a drain current due to the irradiation of light;

FIG. 3B is a graph plotting a light-on drain current and a light-off drain current versus a gate voltage for the measurement of FIG. 3A;

FIG. 3C is a graph showing a measurement result of the drain current due to the irradiation of light;

FIG. 3D is a graph plotting the light-on drain current and the light-off drain current versus the gate voltage for the measurement of FIG. 3C;

FIG. 3E is a graph showing a measurement result of the drain current due to the irradiation of light;

FIG. 3F is a graph plotting the light-on drain current and the light-off drain current versus the gate voltage for the measurement of FIG. 3E;

FIGS. 3G to 3J are graphs showing measurement results of the drain current due to the irradiation of light;

FIGS. 4A to 4H are for describing operations of light-receiving devices of embodiments;

FIGS. 5A and 5B are schematic views showing the relationship between the energy levels of graphene and a citrate ion; and

FIG. 6 is a graph showing the photoresponse of a graphene FET to which DNA is adhered.

### DETAILED DESCRIPTION

According to one embodiment, a light-receiving device includes graphene including a light-receiving part, the light-receiving part being configured to receive light; major electrodes electrically connected with the graphene, the major electrodes including a source electrode and a drain electrode, the light-receiving part being positioned between the source electrode and the drain electrode; a gate electrode electrically connected with the light-receiving part of the graphene via capacitive coupling; a circuit part electrically connected with the major electrode and the gate electrode, the circuit part being configured to apply voltages to the major electrodes and the gate electrode, and measure a current flowing in the major electrodes; and an ionic substance contacting the light-receiving part of the graphene, the ionic substance being one of an anion having an acid dissociation constant of not less than 3 or a cation having an acid dissociation constant of not more than 11.

Embodiments will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

The same or similar components are marked with the same reference numerals.

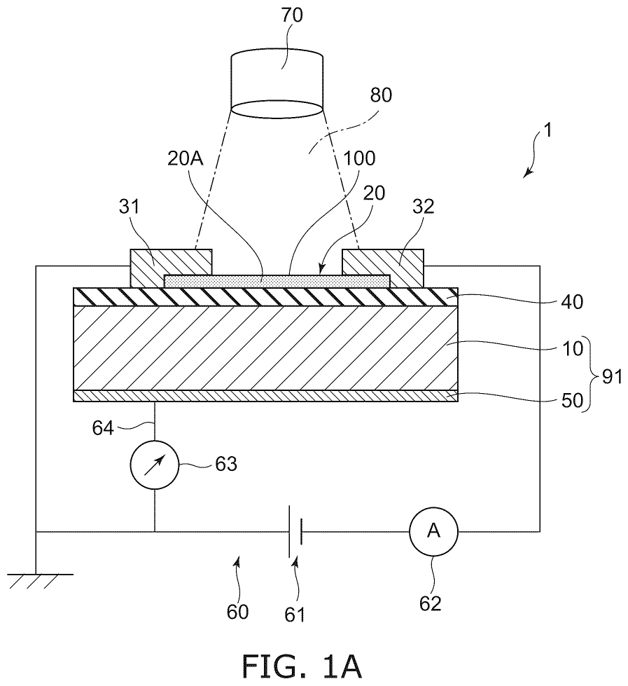

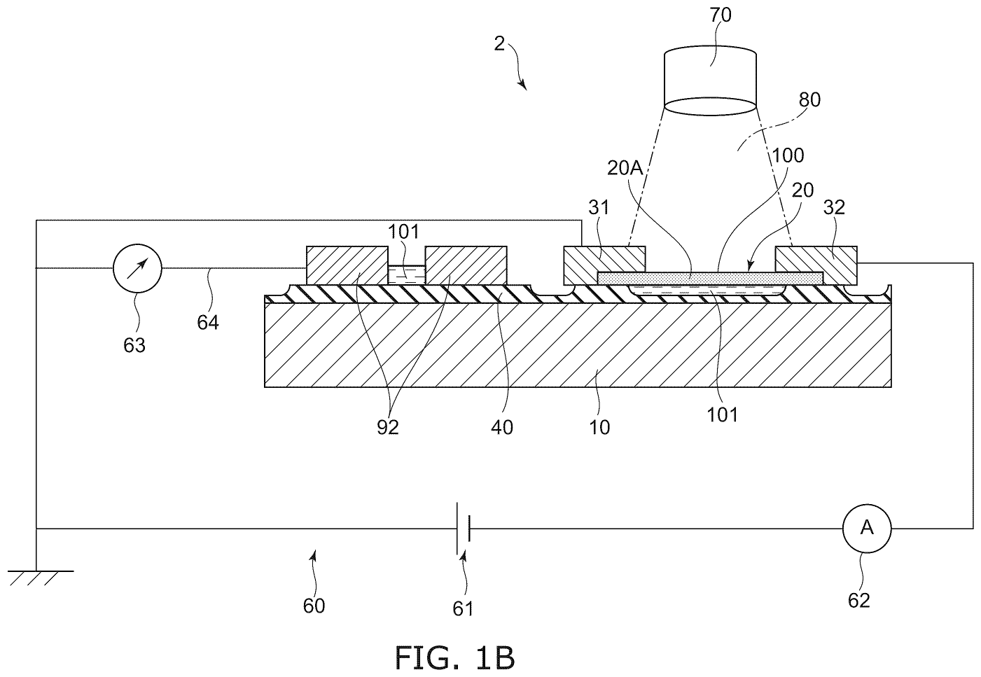

FIG. 1A is a schematic view of a light-receiving device 1 of a first embodiment. The light-receiving device 1 includes graphene 20, major electrodes 31 and 32, a gate electrode 91, a circuit part 60, and an ionic substance 100.

The graphene 20 includes a light-receiving part 20A that is optically exposed to be capable of receiving light 80 from a light source 70. The graphene 20 is favorably single-layer graphene. The graphene 20 is located on a substrate 10 with an insulating film 40 interposed. For example, a silicon substrate can be used as the substrate 10. For example, a silicon oxide film can be used as the insulating film 40.

The major electrodes include the source electrode 31 and the drain electrode 32, and are electrically connected with the graphene 20. The source electrode 31 and the drain electrode 32 are separated from each other on the insulating film 40. A portion of the source electrode 31 contacts the graphene 20; and a portion of the drain electrode 32 contacts the graphene 20. The light-receiving part 20A of the graphene 20 is positioned between the source electrode 31 and the drain electrode 32.

The gate electrode 91 is electrically connected with the light-receiving part 20A of the graphene 20 via capacitive coupling by the insulating film 40. In the example, the gate electrode 91 includes the substrate 10 supporting the graphene 20, and a conductive film 50 located at the lower surface (the back surface) of the substrate 10. The substrate 10 is conductive. For example, a stacked film of titanium, nickel, and gold, etc., can be used as the material of the conductive film 50. By using such a conductive film 50, ohmic contact with the substrate 10, which is made of silicon, is obtained, and excellent adhesion is obtained. The insulating film 40 is positioned between the gate electrode 91 and the graphene 20, and functions as a gate insulating film.

The circuit part 60 is electrically connected with the source electrode 31, the drain electrode 32, and the gate electrode 91. The circuit part 60 includes a power supply 61 configured to apply a voltage to the source electrode 31 and the drain electrode 32, a variable power supply 63 configured to apply a voltage to the source electrode 31 and the gate electrode 91, and a current measurement part 62 configured to measure the drain current flowing between the source electrode 31 and the drain electrode 32.

A drain current flows in the graphene 20 because a potential difference is applied between the source electrode 31 and the drain electrode 32 via the power supply 61. Here, because the graphene 20 has field-effect transistor (FET) characteristics, the magnitude of the drain current is determined by the potential difference with the gate electrode 91 applied from the power supply 63. Here, photoexcitation of the graphene 20 occurs when the light-receiving part 20A is irradiated with the light 80 from the light source 70. At least one of excited electrons generated by the photoexcitation or their holes causes charge transfer with the ionic substance 100; and the electrostatic potential of the ionic substance 100 changes. Because the ionic substance 100 is capacitively coupled with the graphene 20, the change of the electrostatic potential of the ionic substance 100 is added to the gate voltage from the gate electrode 91 as a bias; and the net gate voltage applied to the graphene 20 changes abruptly. Here, the drain current also changes abruptly due to the FET characteristics of the graphene 20. The current measurement part 62, which measures the drain current, measures this series of drain current changes.

The circuit part 60 includes a gate wiring part 64 that electrically connects the source electrode 31 and the gate electrode 91. The variable power supply (the gate voltage application device) 63 is connected to the gate wiring part 64. The gate wiring part 64 is connected to the conductive film 50; and the gate wiring part 64 and the gate electrode 91 have an ohmic contact due to the conductive film 50. The gate voltage is applied from the gate electrode 91 to the graphene 20. The Fermi level of the graphene 20 is modulated by controlling the gate voltage.

The ionic substance 100 is positioned at the light-receiving part 20A of the graphene 20, and contacts the light-receiving part 20A. The acid dissociation constant of the ionic substance 100 is not less than 3 and not more than 11. The light-receiving device 1 includes the ionic substance 100 that is one of an anion having an acid dissociation constant of not less than 3 or a cation having an acid dissociation constant of not more than 11. The ionic substance is citric acid, phosphoric acid, HEPES (4-(2-hydroxyethyl)-1-piperazineethanesulfonic acid), tris(hydroxymethyl)aminomethane (Tris), nucleic acid, an amino group, or an ethylenediamine derivative.

FIG. 1B is a schematic view of a light-receiving device 2 of a second embodiment. Similarly to the light-receiving device 1 of the first embodiment, the light-receiving device 2 also includes the graphene 20, the source electrode 31, the drain electrode 32, a gate electrode 92, the circuit part 60, and the ionic substance 100.

The gate electrode 92 of the light-receiving device 2 is located on the substrate 10 with the insulating film 40 interposed, and is electrically connected with the gate wiring part 64. An ionic liquid 101 is positioned in a recess of the insulating film 40 formed in the lower surface of the graphene 20; and the ionic liquid 101 contacts the lower surface of the light-receiving part 20A. The ionic liquid 101 also contacts the gate electrode 92 on the insulating film 40. The gate electrode 92 is electrically connected with the light-receiving part 20A of the graphene 20 via the ionic liquid 101. However, because the ionic liquid 101 forms an electric double layer at the contact portion with the light-receiving part 20A, it is more accurate to say that the ionic liquid 101 and the light-receiving part 20A are electrically connected via capacitive coupling due to the electric double layer.

The ionic liquid 101 includes a chlorine ion; and the gate electrode 92 is a silver/silver chloride electrode that includes silver chloride at the surface. The silver/silver chloride electrode (the gate electrode 92) applies a potential to the ionic liquid 101, which includes the chlorine ion, by contacting the ionic liquid 101 and causing an oxidation-reduction reaction. The potential of the ionic liquid 101 is controlled to have a constant potential difference with respect to the potential of the silver/silver chloride electrode (the gate electrode 92) according to the Nernst equation. Due to the oxidation-reduction reaction with silver chloride (AgCl) (AgCl+e⁻→Ag+Cl⁻), the chlorine ions (Cl⁻) in the ionic liquid 101 move between the ionic liquid 101 and the surface of the silver/silver chloride electrode (the gate electrode 92) until the potential of the ionic liquid 101 stabilizes.

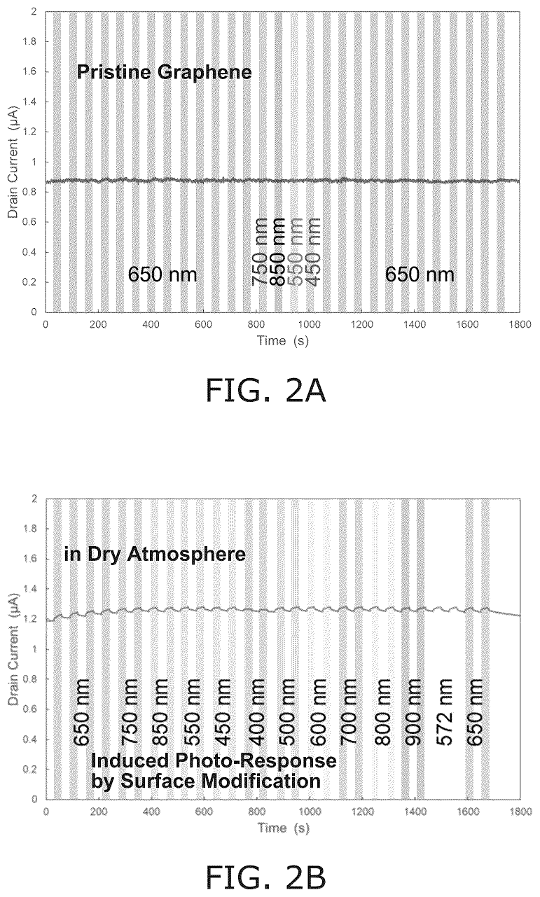

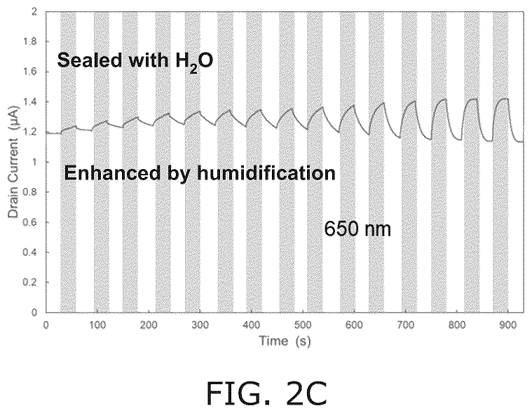

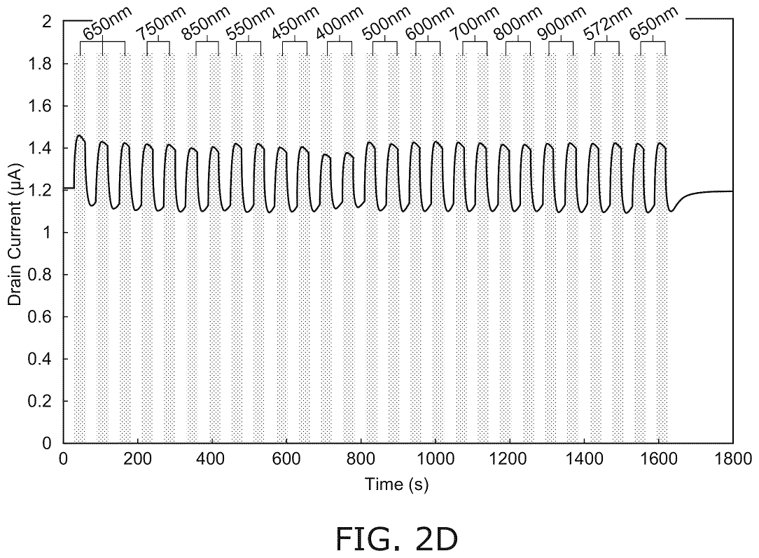

FIG. 2A shows the drain current response when light was irradiated on the light-receiving part 20A (the drain current change with respect to when light is not irradiated) using graphene to which an ionic substance is not adhered. Light having wavelengths of 450 nm, 550 nm, 650 nm, 750 nm, and 850 nm along the time axis (the horizontal axis) was irradiated on the light-receiving part 20A. In FIG. 2A and in FIGS. 2B to 2D, FIG. 3A, FIG. 3C, FIG. 3E, FIGS. 3G to 3J, and FIG. 6 below, light of the wavelengths was irradiated on the light-receiving part 20A in the periods shown in gray (or cross hatching). It can be seen from the measurement result of FIG. 2A that there was no change of the drain current at any wavelength.

FIG. 2B shows the drain current response when light was irradiated on the light-receiving part 20A using graphene with citric acid adhered as an ionic substance having an acid dissociation constant of not less than 1 and not more than 13. Light having wavelengths of 400 nm, 450 nm, 500 nm, 550 nm, 572 nm, 600 nm, 650 nm, 700 nm, 750 nm, 800 nm, 850 nm, and 900 nm was irradiated on the light-receiving part 20A in a dry atmosphere. It can be seen from the measurement result of FIG. 2B that the drain current changed for light of all wavelengths.

FIG. 2C shows the drain current response when light of 650 nm was irradiated in a state in which water and the graphene with citric acid adhered were sealed together. It can be seen that the drain current response gradually increased. This is a phenomenon accompanying a humidity increase inside a sealed container; and it can be seen that the drain current response (hereinbelow, called the photoresponse) accompanying the light irradiation is amplified by the humidify.

FIG. 2D shows the drain current response (the photoresponse) when light of various wavelengths was irradiated on the light-receiving part 20A while maintaining the sealed state of FIG. 2C. Light having wavelengths of 650 nm, 750 nm, 850 nm, 550 nm, 450 nm, 400 nm, 500 nm, 600 nm, 700 nm, 800 nm, 900 nm, 572 nm, and 650 nm along the time axis (the horizontal axis) was irradiated on the light-receiving part 20A. It can be seen from the measurement result of FIG. 2D that the drain current had a large response at each light wavelength. Citric acid, an anionic molecule, can be used as an ionic substance having an acid dissociation constant of not less than 3 and not more than 11, and is known to have three acid dissociation stages, of which the acid dissociation constants are 3.09, 4.75, and 6.41.

To adhere citric acid, a gold nanoparticle solution (100 nm-diameter citric acid dispersion made by CytoDiagnostics) including citric acid as a stabilizing agent was added dropwise and dried. Accordingly, gold nanoparticles also adhered in addition to citric acid, but scanning electron microscope observation performed beforehand shown that almost no gold nanoparticles were adhered. It was found that the contribution to the photoresponse was substantially due to the citric acid because after the gold nanoparticle solution was added dropwise, the few gold nanoparticles that were present before washing also remained when the citric acid, which is water-soluble, was replaced with purified water by washing; however, a photoresponse was not observed for the remaining gold nanoparticles, whereas a photoresponse was observed when citric acid (citric acid monohydrate by FUJIFILM Wako Chemicals Corporation) was added dropwise as an aqueous solution and dried. Hereinbelow, a sample in which citric acid is similarly adhered using citrate-stabilized gold nanoparticles is called “graphene with citric acid adhered”.

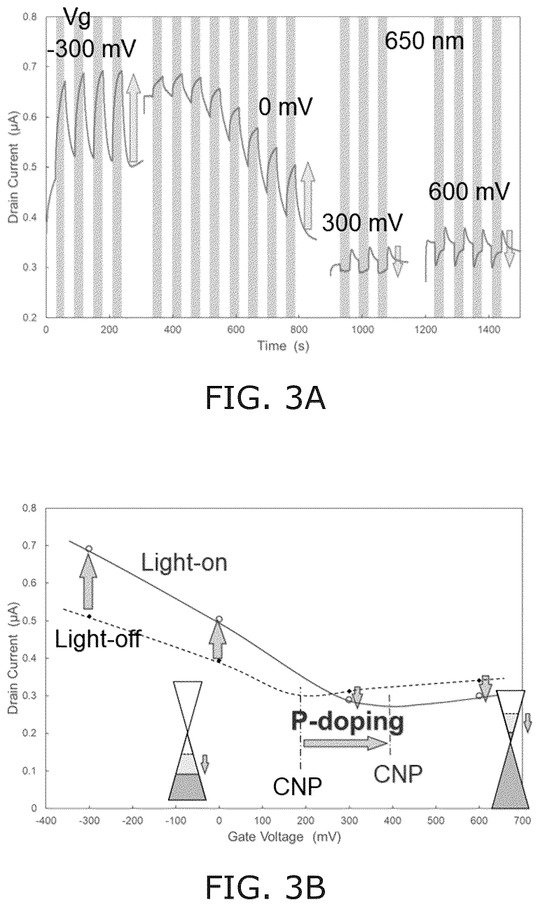

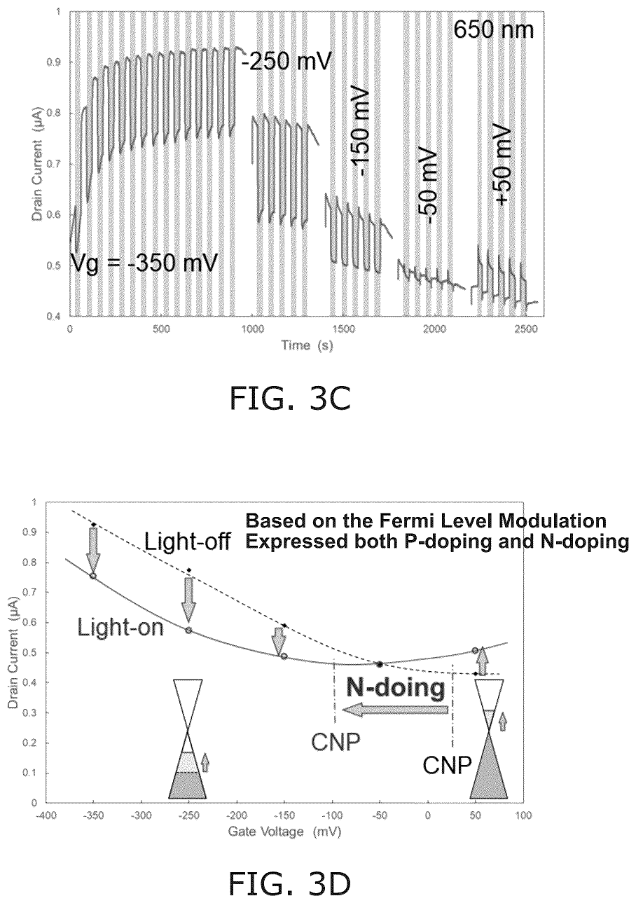

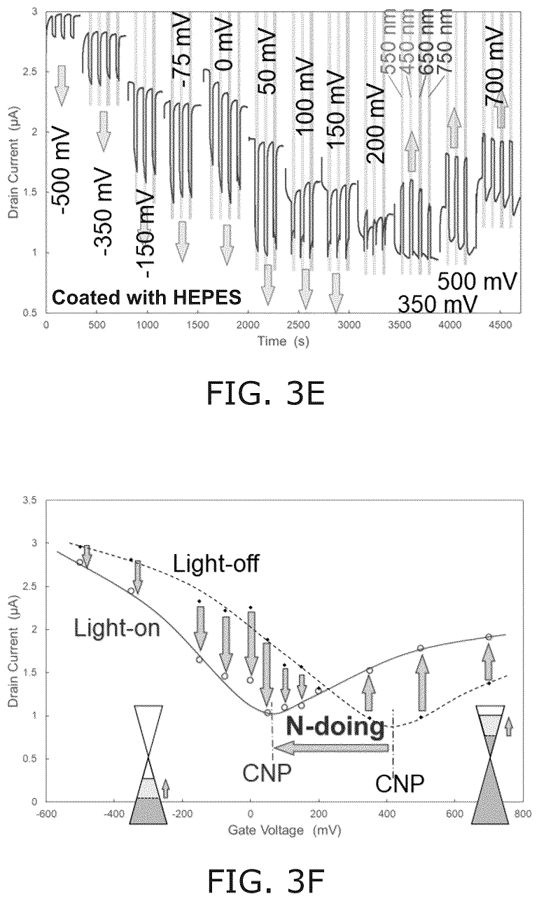

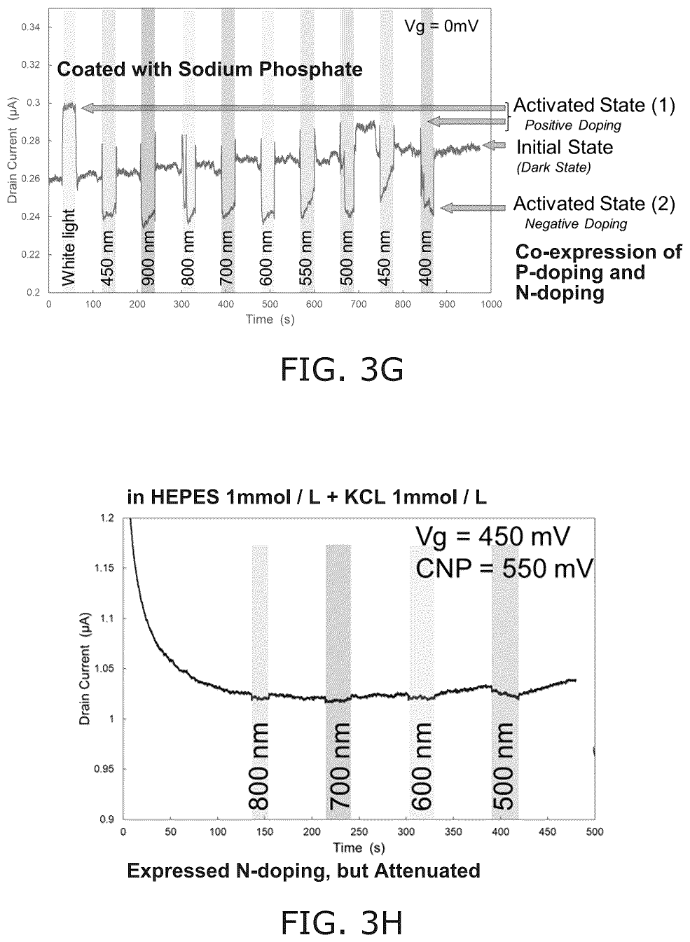

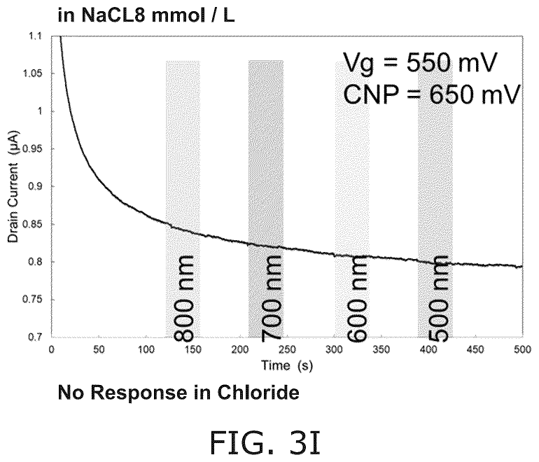

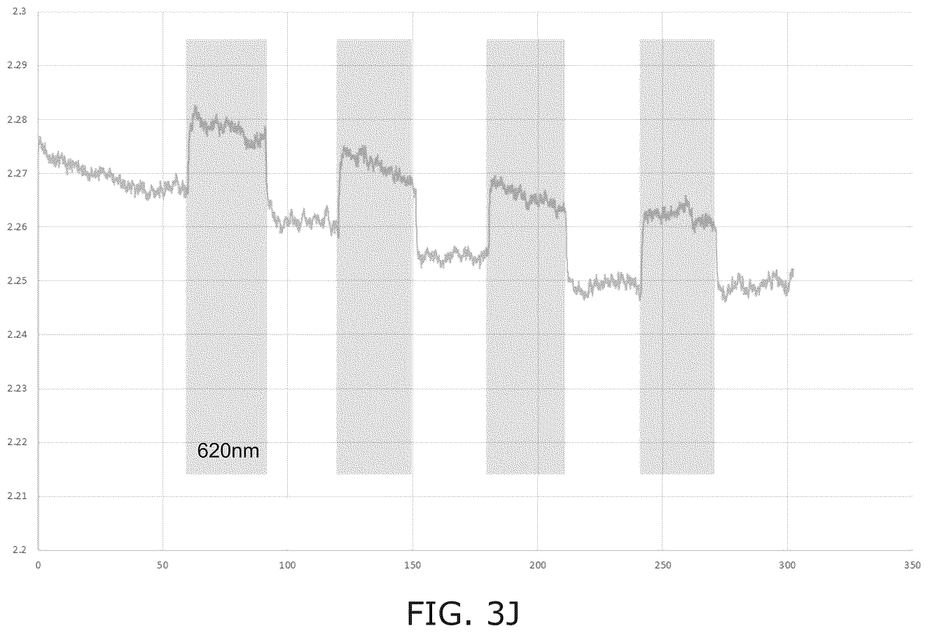

FIGS. 3A to 3D are measurement results of the photoresponse of graphene with citric acid adhered as an ionic substance while modifying the gate voltage (FIGS. 3A and 3C), and plots of the light-on drain current and the light-off drain current acquired in the measurement versus the gate voltage (FIGS. 3B and 3D). FIG. 3B is a plot of the light-on drain current and the light-off drain current acquired in the measurement of FIG. 3A versus the gate voltage. FIG. 3D is a plot of the light-on drain current and the light-off drain current acquired in the measurement of FIG. 3C versus the gate voltage. It can be seen that the light-on drain current and the light-off drain current each have a typical graphene FET characteristic having a V-shaped change (a transfer curve) with respect to the gate voltage. It can be seen that the V-shaped transfer curve shifts in the horizontal direction (i.e., changes in the offset direction of the gate voltage) between light-on and light-off, and the Fermi level of the graphene FET is modulated by the presence or absence of the light irradiation. Here, the modulation of the Fermi level by the light irradiation is in the positive doping direction in FIGS. 3A and 3B, and in the negative doping direction in FIGS. 3C and 3D. The modulation occurs in both the positive direction and the negative direction even for graphene with the same citric acid adhered, and the reason of which is described below.

FIGS. 3E and 3F show the measurement results of the photoresponse of graphene with HEPES adhered as an ionic substance while modifying the gate voltage (FIG. 3E), and a plot of the light-on drain current and the light-off drain current acquired in the measurement versus the gate voltage (FIG. 3F). Similarly, it can be seen that modulation of the Fermi level occurs in the negative doping direction. HEPES is a zwitterion having an anionic sulfonic acid group and a cationic tertiary amino group respectively having acid dissociation constants of 3 and 7.5. To adhere HEPES, 1 mol/L of a HEPES buffer solution (pH of 7.3/Dojindo Laboratories) was added dropwise and dried.

FIG. 3G shows measurement results of the photoresponse of graphene with phosphoric acid adhered as an ionic substance for a gate voltage of 0 mV. For the first light irradiation, the drain current increased, and then decreased at turn-off to the initial current value. The response for the first light irradiation is estimated to be positive doping because it is estimated that the graphene FET is in a hole conduction state for the gate voltage of 0 mV. Then, for the second and subsequent light irradiations, an instantaneous drain current increase occurs, and then the drain current decreases immediately to or below the initial current value. At turn-off as well, an instantaneous drain current increase to or above the initial current value occurs, and then the drain current decreases immediately to the initial current value. In other words, when light is flashed, an instantaneous positive doping occurs, but the negative doping state is stable during the light irradiation. At about 700 seconds, an increased drain current state is maintained when the light is off. In other words, the positive doping state is maintained. The graphene with citric acid adhered shown in FIGS. 3A to 3D suggests that both the positive doping direction and the negative doping direction may be present; however, it is suggested here that positive doping and negative doping may be co-expressed. Similarly to phosphoric acid, citric acid also has three acid dissociation states having acid dissociation constants of 2.12, 7.21, and 12.67. To adhere phosphoric acid, 0.1 mol/L of a sodium phosphate buffer solution (pH of 7.0/FUJIFILM Wako Chemicals Corporation) was added dropwise and dried.

FIGS. 3H and 3I show the drain current response of a graphene FET in aqueous solutions when light is irradiated. FIG. 3H shows the measurement result for a HEPES aqueous solution; and FIG. 3I shows the measurement result for sodium chloride aqueous solution. The gate voltage was applied to the graphene FET via the aqueous solution by using a silver/silver chloride electrode inserted into the aqueous solution. The gate voltages were 450 mV in FIGS. 3H and 550 mV in FIG. 3I, so that each caused the graphene FET to be in a hole conduction state. As shown in FIG. 3H, the light irradiation for the HEPES reduced the drain current, that is, caused a photoresponse in the negative doping direction. However, the magnitude of the response was attenuated compared to the responses in the vapor phase described above. On the other hand, as shown in FIG. 3I, no photoresponse was observed for sodium chloride. Here, the acid dissociation constant of sodium, a cation of sodium chloride, is 13 when taken to be the acid dissociation constant of sodium hydroxide; and the acid dissociation constant of chlorine, an anion, is −3.7 when taken to be the acid dissociation constant of hydrochloric acid. Thus, this means that cations having extremely large acid dissociation constants and anions having extremely small acid dissociation constants have extremely stable acid dissociation states. Reasons that such ions do not contribute to the photoresponse are described below.

FIG. 3J shows the photoresponse of a graphene FET in which a zwitterionic oligomer include equal amounts of glutamic acid and lysine as scaffolding, and a cyclic arginine oligomer is bonded. The irradiation of an LED light of 620 nm increased the drain current, that is, caused positive doping. Here, as described below, it is considered that positive doping is expressed by a cation or by an anion having an acid dissociation constant greater than 6, i.e., an anion having an extremely unstable acid dissociation state. Considering that the acid dissociation constant of glutamic acid, an anion, is 4.25 and the anion in the HEPES solution used in the solid-phase treatment (the treatment of adhering the ionic substance to graphene) is a sulfonic acid group having an acid dissociation constant of 3, it is estimated that the photoresponse is caused by one of lysine (acid dissociation constant of 10.53) or arginine (acid dissociation constant of 12.48), which are cations. However, considering that arginine is a strong base having an acid dissociation constant that is substantially equal to that of calcium hydroxide (acid dissociation constant of 12.7) and has an extremely stable acid dissociation state, it is estimated that the photoresponse is caused by acid-dissociated lysine.

Here, a scaffold peptide having an amino acid sequence of ECKEKCEKECKEKCEKECKEKCEKECK from the N-terminal toward the C-terminal was used as the zwitterionic oligomer including equal amounts of glutamic acid and lysine. Pyrenylmaleimide was mixed with the scaffold peptide aqueous solution in a molar ratio of 3 to pyrene-modify substantially half of the thiol groups of cysteine in the scaffold peptide to be adhered to the graphene surface by a π-π interaction. Subsequently, a TMEA (tris(2-maleimidoethyl)amine (Thermo Fisher Scientific)) solution was added dropwise to maleimide-modify the remaining substantially half of the thiol groups of the scaffold peptide to bond the peptide to have a peptide of sequence CGGGRRRRRRRRRRRRRRRRRRRR from the N-terminal toward the C-terminal, and in which the N-terminal and the C-terminal are cyclized with a peptide bond.

From the measurement results of FIGS. 2A to 3J, photoresponses occurred for citric acid, which is a polyvalent anion having acid dissociation constants of 3.09, 4.75, and 6.41, HEPES, which is a zwitterion having acid dissociation constants of 3 and 7.5, phosphoric acid, which is a polyvalent anion having acid dissociation constants of 2.12, 7.21, and 12.67, and lysine, which is a cation having an acid dissociation constant of 10.53; however, a photoresponse did not occur for the sodium ion, a cation having an acid dissociation constant of 13, or the chlorine ion, an anion having an acid dissociation constant of −3.7. Also, no dependence on the irradiated light wavelength was observed when the photoresponse occurred. In other words, according to the embodiment, a strong response to light over a wide wavelength range is possible by positioning an ionic substance having an acid dissociation constant of not less than 3 and not more than 11 in contact with the graphene surface.

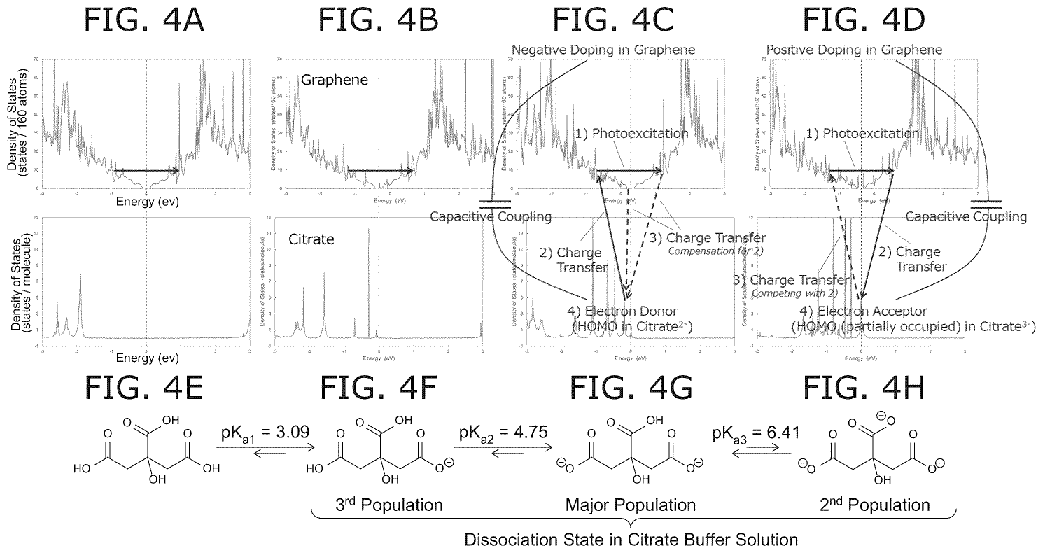

The reason is explained below with reference to FIGS. 4A to 4D. FIGS. 4A to 4D illustrate the partial state density of graphene calculated by first principle calculations based on density functional theory for a composite model of graphene and citric acid. FIGS. 4E to 4H illustrate the partial state density of citric acid, also from first principle calculations. The composite model of graphene and citric acid used in the density of states calculation was determined by calculating the positional relationship between graphene and the molecular structure of citric acid by performing first principle molecular dynamics calculations beforehand. FIG. 4E shows when the citric acid valence was zero; FIG. 4F shows when the citric acid valence was −1; FIG. 4G shows when the citric acid valence was −2; and FIG. 4H shows when the citric acid valence was −3. FIG. 4A illustrates the partial state density of graphene corresponding to FIG. 4E;

FIG. 4B illustrates the partial state density of graphene corresponding to FIG. 4F; FIG. 4C illustrates the partial state density of graphene corresponding to FIG. 4G; and FIG. 4D illustrates the partial state density of graphene corresponding to FIG. 4H. The Fermi level of graphene is controllable by modifying the gate voltage; and the Fermi levels of FIGS. 4A, 4B, 4C, and 4D respectively match the Dirac points because the gate voltage was changeable around the Dirac point in actual experiments using citric acid.

When light having a wavelength of 650 nm is irradiated on graphene, electrons are excited as illustrated by the arrows in FIGS. 4A to 4D.

For citric acid without acid dissociation in FIG. 4E, both the HOMO (Highest Occupied Molecular Orbital) and the LUMO (Lowest Unoccupied Molecular Orbital) were distant to the Fermi level. It can be seen that the energy level at which photoexcitation occurred at the graphene side was in a range in which an orbital level between the HOMO and the LUMO at the citric acid side was not present. In such a state, the photoexcitation at the graphene side had no effect on the citric acid. The HOMO-LUMO bandgap of citric acid is sufficiently large compared to the energy of visible light, and so photoexcitation did not occur in the citric acid even when the visible light was irradiated.

On the other hand, the HOMO was present at the Fermi level vicinity for the acid-dissociated citrate ions shown in FIGS. 4F to 4H. For the monovalent dissociated citrate ion shown in FIG. 4F and the divalent dissociated citrate ion shown in FIG. 4G, the HOMO levels were directly under the Fermi levels. For the trivalent dissociated citrate ion shown in FIG. 4H, the HOMO level straddled the Fermi level. In other words, it can be seen that the electrons were in a partially occupied state in the HOMO level of trivalent citrate ion. The reason that the acid-dissociated citrate ion had a HOMO level at the Fermi level vicinity is described below.

The mechanism by which negative doping may occur in the graphene FET due to light irradiation in the presence of a divalent acid-dissociated citrate ion will now be described with reference to FIGS. 4C and 4G.
(1) When light is irradiated, photoexcitation occurs at the graphene side. FIG. 4C shows the state of the photoexcitation when light having a wavelength of 650 nm was irradiated.
(2) The energy level of the holes remaining in the graphene due to the photoexcitation is low compared to the energy level of the HOMO occupied by electrons at the citrate ion side, and so electrons move from the HOMO of the citrate ion to the graphene holes.
(3) Holes remain in the HOMO of the citrate ion after the electron transfer and have a lower energy level than the excited electrons at the graphene side, and so the excited electrons at the graphene side move into the HOMO of the citrate ion to compensate the fluctuation of the number of electrons due to (2) above.
(4) Among (2) and (3) above, (2) is the predominant major reaction, and so the citrate ion loses electrons and changes toward the positive charge side.
(5) Because the citrate ion and graphene are capacitively coupled, the charge change at the citrate ion side causes electrostatic induction and induces a negative charge at the graphene side. Although a divalent acid-dissociated citrate ion is used in the description, the monovalent acid-dissociated citrate ion also has a HOMO directly under the Fermi level, and so a similar photoresponse may occur.

A mechanism by which positive doping may occur in the graphene FET due to light irradiation in the presence of a trivalent acid-dissociated citrate ion will now be described with reference to FIGS. 4D and 4H.
(1) When light is irradiated, photoexcitation occurs at the graphene side. FIG. 4D shows the state of the photoexcitation when light having a wavelength of 650 nm was irradiated.
(2) The energy level of the excited electrons generated in the graphene by the photoexcitation is high compared to the energy level of the HOMO of the citrate ion. Here, the HOMO of the citrate ion is only partially occupied by electrons, and so the excited electrons of the graphene move into the HOMO of the citrate ion.
(3) On the other hand, the energy level of the holes remaining at the graphene side due to the photoexcitation is lower than the energy level of the HOMO of the citrate ion, and so electron transfer from the HOMO of the citrate ion to the holes at the graphene side also occurs.
(4) Although competition occurs between (2) and (3) above, when (2) is predominant, the citrate ion becomes an electron acceptor and changes to the negative charge side.
(5) Because the citrate ion and graphene are capacitively coupled, the charge change at the citrate ion side causes electrostatic induction and induces a positive charge at the graphene side.

By changing the acid dissociation state of citric acid as described above, a state in which a positive charge is injected and a state in which a negative charge is injected are possible for graphene when light is irradiated. The acid dissociation constant of citric acid changing from divalent to trivalent is 6.41, which is substantially neutral. In other words, citric acid may be divalent or trivalent according to a slight presence of impurity ions, etc. It is considered that this is the reason that both a photoresponse in the positive doping direction and a photoresponse in the negative doping direction occur. Phosphoric acid also dissociates in multiple stages similarly to citric acid, and therefore can be estimated to have a similar behavior. When the pH is at the vicinity of the acid dissociation constant, ions with valences around the vicinity will be present. In such a case, positive doping and negative doping due to the light irradiation is expected to compete. The co-expression of the positive doping and the negative doping shown in FIG. 3G is estimated to be in such a state.

In the mechanism of the photoresponse described above, the graphene side of the zero-gap material is excited by the light irradiation; and the citric acid is not affected directly by the light irradiation. As a result, the photoresponse has no wavelength dependence, and is not affected by the HOMO-LUMO bandgap of citric acid.

The reason that the HOMO level of citric acid is expressed at the Fermi level vicinity of graphene when acid-dissociated citric acid is at the graphene vicinity will now be described. First, charge density analysis using Mulliken charges of the results of the density of states calculation for the composite system of graphene and citric acid was performed, and the number of electrons held by citric acid was determined. From these results, the results of determining the actual valence of the citrate ion coexisting with graphene and the change number from the state before the interaction with graphene, i.e., the charge transfer number with graphene, are shown in Table 1.

TABLE 1
(Mulliken charge)

| Initial Valence State | citrate (−1) | citrate (−2) | citrate (−3) |
|---|---|---|---|
| Actural Number of Valences | −0.2 | −1.0 | −1.3 |
| Number of Electron Transfer | 0.8 | 1.0 | 1.7 |
| (Citrate to Graphene) | | | |

As a result, it was found that monovalent citrate ion had a valence of 0.2 after the interaction with graphene; divalent citrate ion became monovalent; and trivalent citrate ion had a valence of 1.3. In other words, it can be seen that for the citrate ion of each valence, the number of electrons was reduced from the initial state, and electrons moved into the graphene. It can also be seen that the number of electrons transferred increased as the valence increased from monovalent to trivalent.

Here, both monovalent and trivalent citrate ions have HOMO levels at the Fermi level vicinity of graphene. From the results described above, it can be estimated that the energy level of the HOMO in the initial state was higher because more electrons were held in the initial state.

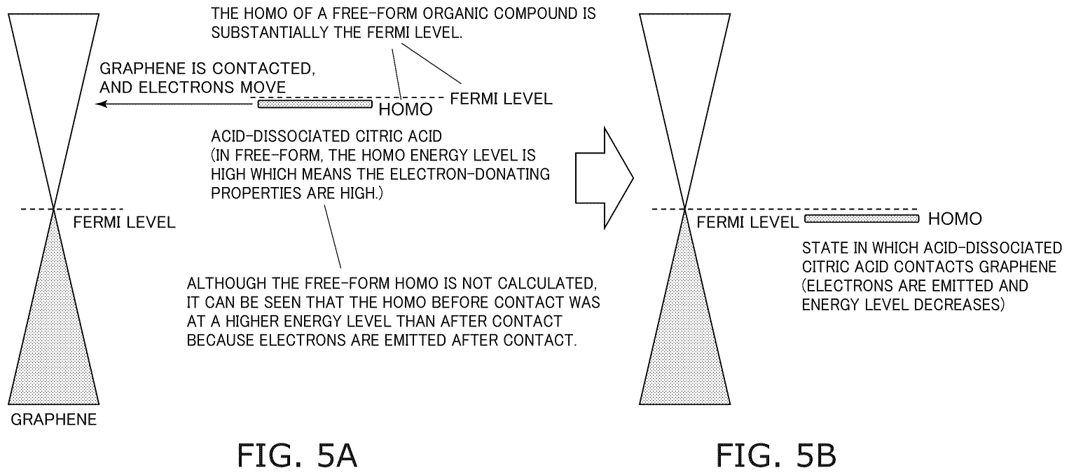

FIGS. 5A and 5B show the relationship between the energy levels of graphene and a citrate ion. As described above, the citrate ion has the HOMO at an extremely high energy level in the initial state. Here, in an isolated molecule that has a HOMO-LUMO bandgap, the Fermi level substantially matches the HOMO level. Accordingly, the Fermi level of a solitary citrate ion in an isolated state is extremely high, that is, has a small work function. In other words, an acid-dissociated citrate ion has electron-donating properties. Here, when graphene approaches, electrons move from the citrate ion having the high Fermi level (HOMO level) to the graphene side having the low Fermi level. The Fermi level (the HOMO level) of the citrate ion donating the electrons is reduced to be equal to the Fermi level of graphene. As a result, the HOMO level of the citrate ion interacting with graphene is positioned at the vicinity of the Fermi level of graphene. As shown in Table 1, the electron-donating properties increase as the valence of citric acid increases, and so it can be estimated that a higher valence means that the HOMO level in the initial state was a higher energy level. Even after the interaction with graphene, the trivalent citrate ion is in a partially occupied state with the HOMO having an energy level slightly higher than the Fermi level of graphene, and it is estimated that this is because the HOMO level in the initial state was higher.

The mechanism described above is due to citric acid holding more electrons due to acid dissociation which increases the energy level of the HOMO; therefore, acid dissociation is a requirement. As shown in FIG. 2C, etc., the increase of the photoresponse due to humidification is estimated to be due to the promotion of acid dissociation by humidification. Higher electron-donating properties due to acid dissociation means that the acid dissociation state is unstable, which is a feature of an anion forming a so-called weak acid (in other words, an anion having a large acid dissociation constant). Accordingly, the mechanism described above is estimated to be a mechanism that is generically expressed in anions, other than citric acid, that have large acid dissociation constants. It is estimated that the occurrence of the photoresponse for phosphoric acid and HEPES in the experiment results described above is due to this reason. On the other hand, it is estimated that there was no occurrence of a photoresponse for chlorine ions, which form strong acids, because chlorine ions have extremely stable dissociation states and have no electron-donating properties. The actual acid dissociation constant of a chlorine ion is extremely small at −3.7.

The explanation above is for anions that form weak acids, but it is estimated that a similar phenomenon occurs for cations forming weak bases as well. In such a case, the cation emits electrons due to acid dissociation, and the state of the cation becomes slightly unstable, i.e., an electron-accepting state. In the electron-accepting state, the LUMO is at a low energy level; and the Fermi level is at the vicinity of the even lower HOMO level. Here, when the LUMO level of the cation is lower than or near the Fermi level of graphene, electrons are donated from the graphene to the LUMO of the cation; the Fermi level of the cation that was much lower than the Fermi level of graphene is increased; and the two match. At this time, the electrons of the LUMO are in a partially occupied state, and are at the Fermi level vicinity. When light is irradiated in this state, the excited electrons generated by the photoexcitation at the graphene side are at a higher level than the partially-occupied LUMO level, and so electrons move from the graphene to the cation. Because the cation changes in the negative charge direction, a positive charge is induced in the graphene via the capacitive coupling with the graphene. It is estimated that the positive doping that occurred in FIG. 3J was due to the occurrence of the photoresponse of the mechanism described above due to lysine, which is a cation having an acid dissociation constant of 10.53.

Similar photoresponses may be expressed for tris(hydroxymethyl)aminomethane (Tris), a cation having an acid dissociation constant of 8.06 (25° C.), and an ethylenediamine derivative, which is a cation having a multistage acid dissociation. Examples of ethylenediamine derivatives include ethylenediamine having acid dissociation constants f 4.42 and 9.21, diethylenetriamine having acid dissociation constants of 4.42, 9.21, and 10.02, triethylenetetraamine having acid dissociation constants of 3.32, 6.67, 9.2, and 9.92, etc. Nucleic acid also is a weak base having acid dissociation constants of 4.4 for adenine, 4.6 for cytosine, 2.9 for guanine, and 0.8 for thymine and exhibits a similar photoresponse.

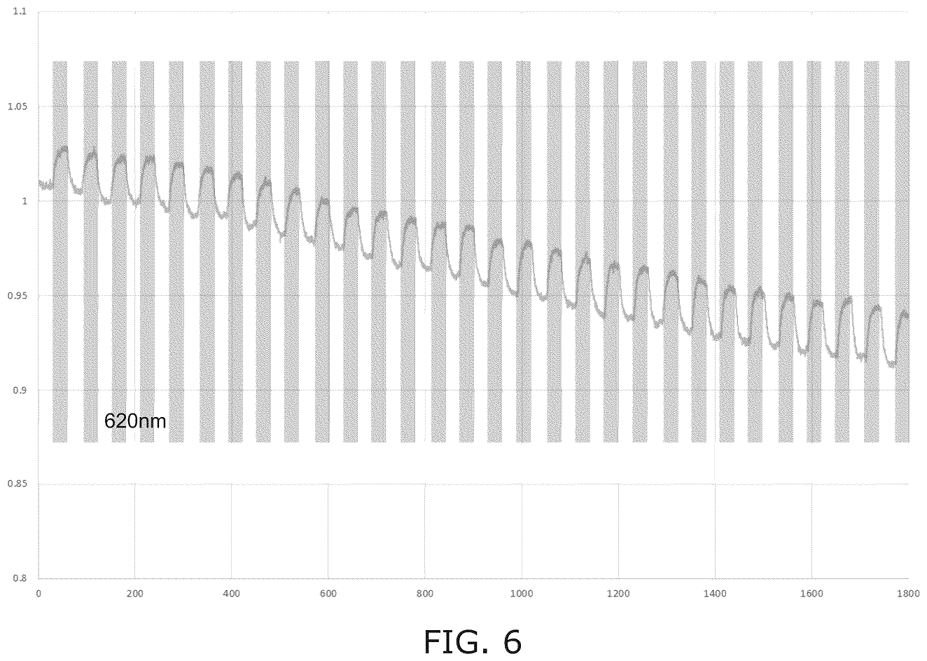

FIG. 6 shows a photoresponse of a graphene FET with DNA adhered.

Here, to adhere DNA, an aqueous solution of DNA having a base sequence of GACAAGGAAAATCCTTCAATGAAGTGGGTC from the 5′ end toward the 3′ end and having a thiol-modified 5′ end was added dropwise and dried.

From the description above, in a graphene FET with an ionic substance having an acid dissociation constant of not less than 3 and not more than 11 adhered, light irradiation modulates the Fermi level of the graphene FET and causes the expression of a drain current change. More accurately, in a graphene FET to which one of an anion having an acid dissociation constant of not less than 3 or a cation having an acid dissociation constant of not more than 11 is adhered, light irradiation modulates the Fermi level and causes the expression of a drain current change.

The phenomenon that is expressed by the direct action of the light irradiation is photoexcitation in graphene, which is a zero-gap material; and the light irradiation has no direct effect on the ionic substance. Accordingly, a strong response is independent of specific wavelengths, and is possible for light of a wide wavelength range. Based on the mechanism described above, if the Fermi level of graphene is adjusted to the Dirac point by controlling the gate voltage applied to the graphene, a response is possible even for infrared. In other words, the gate voltage is set to a voltage so that the electrical resistance between the source electrode 31 and the drain electrode 32 is a maximum.

Substantially no photoresponse was observed when the density of the ionic substance contacting the graphene was not more than 0.3 ions/nm². A photoresponse was confirmed when the density of the ionic substance contacting the graphene was not less than 0.6 ions/nm² and not more than 1 ion/nm².

The acid dissociation of an ionic substance is promoted by humidification. Therefore, an amplification of the photoresponse by humidifying the light-receiving part 20A of the graphene 20 was confirmed compared to when humidification was not performed.

For example, the light-receiving part 20A can be positioned in a humidified space by sealing the light-receiving part 20A inside a container in a humidified atmosphere.

For example, a mechanism that exposes the light-receiving part 20A to a humidified atmosphere may be included.

For example, the light-receiving part 20A may be positioned in an electrolyte solution.

For example, the ionic substance 100 may contact the light-receiving part 20A together with a hydrophilic substance.

A method for manufacturing the light-receiving device 1 shown in FIG. 1A can include the following processes.

Graphene is formed by CCVD (Carbon Chemical Vapor Deposition) on a Cu foil. The graphene is transferred to the front surface of a silicon wafer including the conductive film 50 formed at the back surface and a silicon oxide film formed at the front surface; and the graphene is patterned. Subsequently, conductive films used to form the source electrode 31, the drain electrode 32, wiring parts, etc., are formed at the front surface of the wafer, and are patterned. After hydrophilizing treatment of the graphene surface, an aqueous solution that includes the desired ionic substance is added dropwise to the graphene surface and dried to position the ionic substance at the graphene surface. In the hydrophilizing treatment of the graphene surface, for example, an aqueous solution of pyrene-modified PEG (polyethylene glycol) or pyrene-modified zwitterion is added dropwise to the graphene surface, left for not less than 30 minutes, and then washed.

The method for manufacturing the light-receiving device 2 shown in FIG. 1B can include the following processes.

Graphene is formed by CCVD on a Cu foil. The graphene is transferred to the front surface of a silicon wafer including the conductive film 50 formed at the back surface and a silicon oxide film formed at the front surface; and the graphene is patterned. Subsequently, conductive films used to form the source electrode 31, the drain electrode 32, wiring parts, etc., are formed at the front surface of the wafer, and are patterned. The gate electrode 92 is formed at the front surface of the wafer. The process of forming the gate electrode 92 can include a process of forming AgCl by forming a Ag film and then patterning. AgCl can be formed by treating the Ag surface with 1,3-diaminopropanetetraacetic acid ferric ammonium salt monohydrate (PDTA·Fe(III)) to cause the following reaction. PDTA·Fe³⁺+Ag+NaCl→PDTA·Fe²⁺+AgCl+Na⁺. After a protective film of the gate electrode 92 is formed, buffered hydrofluoric acid is used to remove the silicon oxide film under the graphene and form a recess. Subsequently, an organic solvent is used to remove the protective film of the gate electrode. Subsequently, supercritical cleaning and drying are performed. Here, the process from buffered hydrofluoric acid treatment to supercritical cleaning is a continuous process and does not allow drying partway. Subsequently, after hydrophilizing treatment of the graphene surface, an aqueous solution that includes the desired ionic substance is added dropwise to the graphene surface, and then supercritical cleaning and drying are performed to position the ionic substance at the graphene surface. Here as well, the process from hydrophilizing treatment to supercritical cleaning is a continuous process and does not allow drying partway. Finally, the recess formed under the graphene is filled with an ionic liquid; and the ionic liquid is filled to contact the gate electrode.

For graphene, the law of conservation of momentum does not hold and photoexcitation does not occur when the light energy is less than 2 times the energy level difference between the Fermi level and the Dirac point. By scanning the gate voltage to scan the Fermi level toward the Dirac point from a lower energy level than the Dirac point, photoexcitation occurs at the wavelength of the irradiated light. The wavelength of the irradiated light can be identified by scanning the gate voltage. When the wavelength of the received light is known, a photoresponse can be expressed by causing the Fermi level to approach the Dirac point within an energy range that is not more than ½ of the light energy at the wavelength. Also, the light of not less than a certain wavelength can be cut by applying the gate voltage to cause the Fermi level of graphene to be distant to the Dirac point by not less than ½ of the light energy at the wavelength.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A light-receiving device, comprising:
graphene including a light-receiving part, the light-receiving part being configured to receive light;
major electrodes electrically connected with the graphene, the major electrodes including a source electrode and a drain electrode, the light-receiving part being positioned between the source electrode and the drain electrode;
a gate electrode electrically connected with the light-receiving part of the graphene via capacitive coupling;
a circuit part electrically connected with the major electrode and the gate electrode, the circuit part being configured to
apply voltages to the major electrodes and the gate electrode, and
measure a current flowing in the major electrodes; and
an ionic substance contacting the light-receiving part of the graphene,
the ionic substance being one of an anion having an acid dissociation constant of not less than 3 or a cation having an acid dissociation constant of not more than 11.

2. The device according to claim 1, wherein
the gate electrode includes a substrate supporting the graphene.

3. The device according to claim 1, wherein
the gate electrode is electrically connected with the light-receiving part of the graphene via an ionic liquid.

4. The device according to claim 3, wherein
the ionic liquid contacts a lower surface of the light-receiving part.

5. The device according to claim 3, wherein
the ionic liquid includes a chlorine ion, and
the gate electrode is a silver/silver chloride electrode.

6. The device according to claim 1, wherein
the light-receiving part is positioned in a humidified space.

7. The device according to claim 1, further comprising:
a mechanism configured to expose the light-receiving part to a humidified atmosphere.

8. The device according to claim 1, wherein
the light-receiving part is positioned in an electrolyte solution.

9. The device according to claim 1, wherein
the ionic substance contacts the light-receiving part together with a hydrophilic substance.

10. The device according to claim 1, wherein
the ionic substance is citric acid, phosphoric acid, HEPES (4-(2-hydroxyethyl)-1-piperazineethanesulfonic acid), tris(hydroxymethyl)aminomethane (Tris), nucleic acid, an amino group, or an ethylenediamine derivative.
